(19) United States
(12) Patent Application Publication
(10) Pub. No.: US 2025/0133963 A1
(43) Pub. Date: Apr. 24, 2025

(54) Method for Manufacturing a Thermoelectric Device Equipped with a Heat Sink

(71) Applicant: COMMISSARIAT A L'ENERGIE ATOMIQUE ET AUX ENERGIES ALTERNATIVES, Paris (FR)

(72) Inventors: Guillaume SAVELLI, Grenoble (FR); Maxime BAUDRY, Grenoble (FR); Guilhem ROUX, Grenoble (FR)

(73) Assignee: COMMISSARIAT A L'ENERGIE ATOMIQUE ET AUX ENERGIES ALTERNATIVES, Paris (FR)

(21) Appl. No.: 18/919,655

(22) Filed: Oct. 18, 2024

(30) Foreign Application Priority Data
Oct. 20, 2023 (FR) 2311393

(51) Int. Cl. H10N 10/01; H10N 10/13

(52) U.S. Cl. CPC H10N 10/01; H10N 10/13

(57) ABSTRACT

The invention relates to a method for manufacturing a thermoelectric device equipped with a heat sink, comprising the following steps:
A) making (100) a first portion of said thermoelectric device, said first portion being equipped with a heat sink, step A) during which a first series of studs made of a semiconductor material with a given type of doping is deposited by additive manufacturing;
B) producing (200) a second portion of the thermoelectric device, step B) during which a second series of studs made of a semiconductor material with another type of doping is deposited by additive manufacturing;
C) assembling (300) the second portion of the device to the first portion.

### TECHNICAL FIELD OF THE INVENTION

The invention relates to the field of manufacturing thermoelectric devices equipped with a heat sink.

### TECHNICAL BACKGROUND

FIG. 1 shows a thermoelectric device without a heat sink. FIG. 2 shows an enlarged, partially exploded view of the thermoelectric device shown in FIG. 1. FIG. 3 shows a heat sink configured to be installed against one face of the thermoelectric device.

Such a thermoelectric device 10 typically comprises two substrates 11, 12 made of an electrically non-conductive material, often ceramic, and on which are mounted metal connections C11, C12 from which extend studs Pₚ, Pₙ made of p- and n-type semiconductor materials respectively. These studs Pₚ, Pₙ are electrically connected in series. Thermally, however, such a thermoelectric device 10 operates in parallel.

The electrical performance of a thermoelectric device in generator mode is given by:
an internal electrical resistance Rᵢₙₜ=N×ρₙₚ×L/A+Rₘₑₜ+R_{c} with: N, the number of np junctions, L, the length of a stud, A, the cross-sectional area of a stud, and ρₙₚ, the resistivity of the np junction, these various parameters allowing to define the total resistance of the studs, Rₘₑₜ, the total resistance of the metal connections, and R_{c}, the total resistance of the contacts;
a voltage V generated (generator mode) by the thermoelectric device under the effect of a temperature difference ΔT at the ends of the thermoelectric device: V=N×Sₙₚ×ΔT avec Sₙₚ=Sₚ−Sₙ, the Seebeck coefficients of the p and n stud materials, respectively.

The useful electrical power Pᵤ is then written by definition: Pᵤ=V²/4Rᵢₙₜ.

In order to have a high power, it is therefore necessary to have a high voltage in particular, and therefore to have a high ΔT, hence the interest of the heat sink 20, mounted against the substrate 12 for example.

Typically, the thermoelectric device 10 and the heat sink 20 are manufactured separately, and a final assembly is then performed between the two.

As far as the thermoelectric device is concerned, it is necessary to provide a substrate made of electrically insulating material and to deposit the various metal connections. This is done for each substrate 11, 12. The semiconductor material studs are typically produced by sintering. To this end, plates of the semiconductor material from which the semiconductor studs are to be made are sintered and then the plots are cut to the desired dimensions. It is understood that this operation will be performed for the p-doped studs on the one hand and the n-doped studs on the other. Once these studs have been obtained, they need to be placed in the right place on the metal connections C11, C12 and their mechanical strength needs to be ensured on these studs, for example by brazing.

The heat sink 20 consists of a base BSE from which a heat dissipation structure SDT extends. The heat sink 20 is typically made of a material with good thermal conductivity. It may be manufactured in various ways, for example by machining a solid block of the material from which it is made, to obtain a heat dissipation structure SDT in the form of fins (FIG. 3) or other.

The thermoelectric device 10 itself and the heat sink 20 may be assembled using a paste capable of hardening under the effect of heat (thermal paste) and/or by mechanical assembly. FIG. 4 shows, for example, how the thermoelectric device 10 and the heat sink 20 are assembled using a thermal paste PT.

There are many different steps in the manufacturing method. This has an impact on the production time and the manufacturing costs. Furthermore, the technique used to manufacture the semiconductor studs only allows parallelepiped shapes to be produced in practice. This limits the scope for sizing the thermoelectric device, particularly with regard to the intended application and the technical constraints that this application imposes.

One objective of the invention is to propose a method for manufacturing a thermoelectric device equipped with a heat sink that does not have at least one of the aforementioned disadvantages.

### SUMMARY OF THE INVENTION

To solve the above objective, the invention proposes a method for manufacturing a thermoelectric device equipped with a heat sink comprising the following steps:
A) making a first portion of said thermoelectric device, said first portion being equipped with a heat sink, according to the following sub-steps:
   providing a heat sink equipped with a base, said base being flat and made of an electrically insulating material,
   depositing a first series of metal connections on the base of the heat sink in a predefined pattern, and
   depositing, by additive manufacturing, a first series of studs made of a semiconductor material with a given type of doping so that a semiconductor stud is deposited on one and only one of the two ends of each metal connection of the first series of metal connections,
B) producing a second portion of the thermoelectric device in the following sub-steps:
   supplying a plate made of an electrically insulating material,
   depositing a second series of metal connections on said plate, in a pattern identical to that of the first series of metal connections, and
   depositing, by additive manufacturing, a second series of studs made of a semiconductor material with another type of doping so that a semiconductor stud is deposited on one and only one of the two ends of a metal connection of the second series of metal connections,
C) assembling the second portion of the device to the first portion of the device in the following sub-steps:
   arranging a free end of a semiconductor stud of the first portion of the device against a free end of each metal connection of the second portion of the device, and at the same time arranging a free end of a semiconductor stud of the second portion of the device against a free end of each metal connection of the first portion of the device, and
   performing a hot pressing.

The method according to the invention may comprise at least one of the following additional steps, taken alone or in combination:
the heat sink supplied in step A) is made, as a whole, of an electrically insulating material, for example ceramic;
   the plate supplied in step B) is made of a material identical to that of the heat sink supplied in step A);
   the heat sink provided in step A) comprises a heat dissipating structure extending from its base, said heat dissipating structure being made of a material selected from steel, for example 316L steel, Aluminum (Al), Titanium (Ti), Copper Zirconium alloy (CuZr) or graphite;
   the base of the heat sink is made of a material chosen from a mica, a polymer or a ceramic, for example Marcor®;
   the plate provided in step B) is configured to form a further heat sink, for example by the presence of channels within said plate;
   the heat sink supplied in step A) is chosen from a finned heat sink, a stud heat sink, for example formed by solid cylinders, or a channel heat sink;
   during step A), at least one series of additional studs made of a semiconductor material with the same type of doping as the semiconductor studs of the first series of studs is deposited so that an additional semiconductor stud is deposited at the end of each metal connection of the first series of metal connections, parallel to the semiconductor stud already present in the first series of studs; and during step B), at least one other series of additional studs made of a semiconductor material with the same type of doping as the studs of the second series of studs is deposited so that an additional semiconductor stud is deposited at the end of each metal connection of the second series of metal connections, parallel to the semiconductor stud already present in the second series of studs;
   the material forming the semiconductor studs is chosen from Silicon (Si), Silicon Germanium (SiGe), Bismuth Telluride (Bi2Te3), or from the Skutterudite family;
   said additive manufacturing technique is chosen from: laser melting on a powder bed, for example selective laser melting or selective laser sintering, or direct energy deposition.

### BRIEF DESCRIPTION OF THE FIGURES

Further objects and characteristics of the invention will become clearer in the following description, made with reference to the attached figures, wherein:

FIG. 5 schematically represents the main manufacturing steps of the method according to the invention;

FIG. 6a, FIG. 6b and FIG. 6c represent, in the context of an example of an embodiment in accordance with the invention, the various sub-steps of the first main step of the manufacturing method illustrated in FIG. 5;

FIG. 7a, FIG. 7b and FIG. 7c represent, in the context of the same example of embodiment, the various sub-steps of the second main step of the manufacturing method shown in FIG. 5;

FIG. 8 shows, in the scope of the same example of embodiment, the thermoelectric device obtained after implementation of the third and last main step of the manufacturing method shown in FIG. 5;

FIG. 9 shows different shapes of semiconductor studs that may be obtained using the additive manufacturing technique employed in the context of the invention;

FIG. 10 represents another type of thermoelectric device that may be obtained using the manufacturing method in accordance with the invention;

FIG. 11 represents yet another type of thermoelectric device that may be obtained using the manufacturing method in accordance with the invention;

FIG. 12 represents a type of heat sink that may be used;

FIG. 13 is another type of heat sink that may be used.

### DETAILED DESCRIPTION OF THE INVENTION

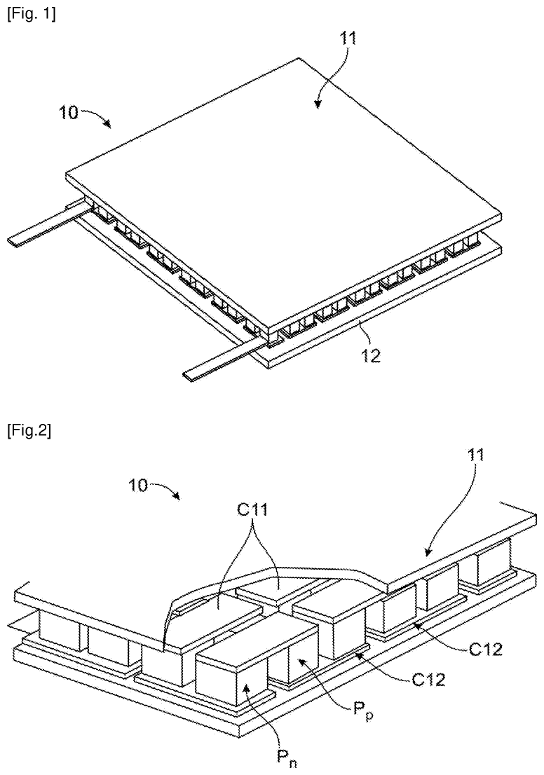

As shown schematically in FIG. 5, the invention relates to a method for manufacturing a thermoelectric device DTE equipped with a heat sink DT, comprising the following steps:
A) making 100 a first portion PP of the thermoelectric device DTE, said first portion being equipped with a heat sink;
B) making 200 a second portion DP of the thermoelectric device DTE; and
C) assembling 300 the second portion DP of the device DTE to the first portion PP of the device DTE.

The manufacture of a thermoelectric device DTE for each of the main manufacturing steps A), B) and C) has been illustrated using a more practical example.

Step A) is carried out in the following sub-steps.

Firstly, a heat sink DT equipped with a base BSE is provided, said base BSE being flat and made of an electrically insulating material.

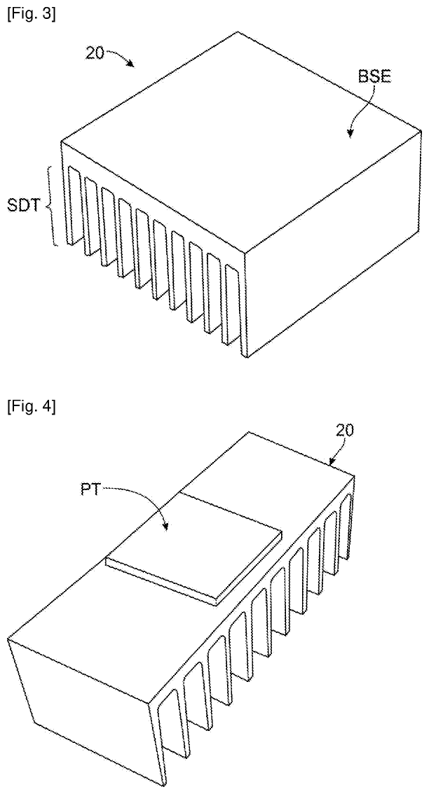

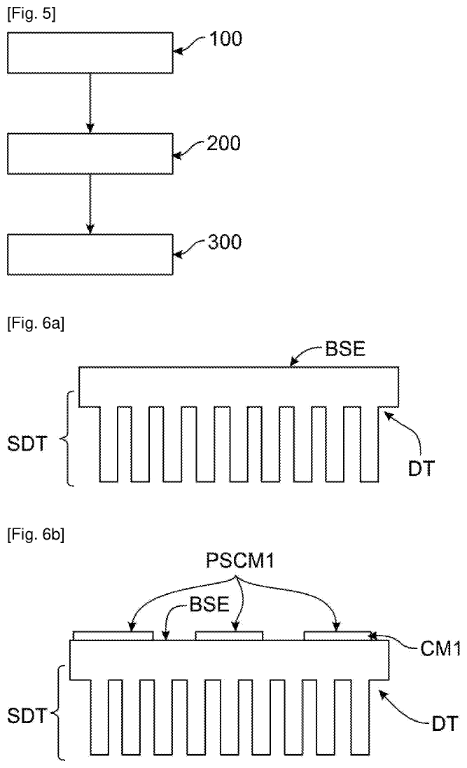

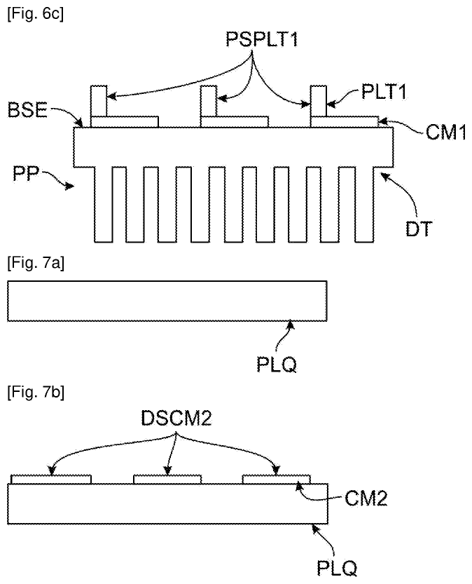

The result is the part shown in FIG. 6a.

A first series of metallic electrical connections PSCM1 is then deposited on the base BSE of the heat sink DT in a predefined pattern. This may be done, but is not limited to, by chemical vapor deposition (CVD) or physical vapor deposition (PVD).

The result is the part shown in FIG. 6b.

The base BSE of the heat sink DT is used as a substrate for depositing the metal connections. This simplifies production and saves time. This also allows to reduce the thickness of the device at this point, thereby allowing to reduce the overall thermal resistance.

Next, a first series of studs PSPLT1 made of a semiconductor material with a given type of doping (n doping, for example) is deposited so that a semiconductor stud PLT1 is deposited on one and only one of the two ends of each metal connection CM1 of the first series of metal connections PSCM1.

This leads to the part shown in FIG. 6c, which forms the first portion PP of the thermoelectric device DTE.

It should be noted that in the invention, the semiconductor studs are deposited by additive manufacturing.

There are several additive manufacturing techniques that may be suitable for the purposes of the invention.

A technique known as laser melting on a powder bed may be used. In this case, the powder is deposited in the form of a powder bed and then densified with a laser beam. This may be either selective laser melting (SLM) or selective laser sintering (SLS).

Alternatively, a direct energy deposition (DED) technique may be used. In this case, the powder is deposited and densified directly by a laser or electron beam.

Step B) is carried out in the following sub-steps.

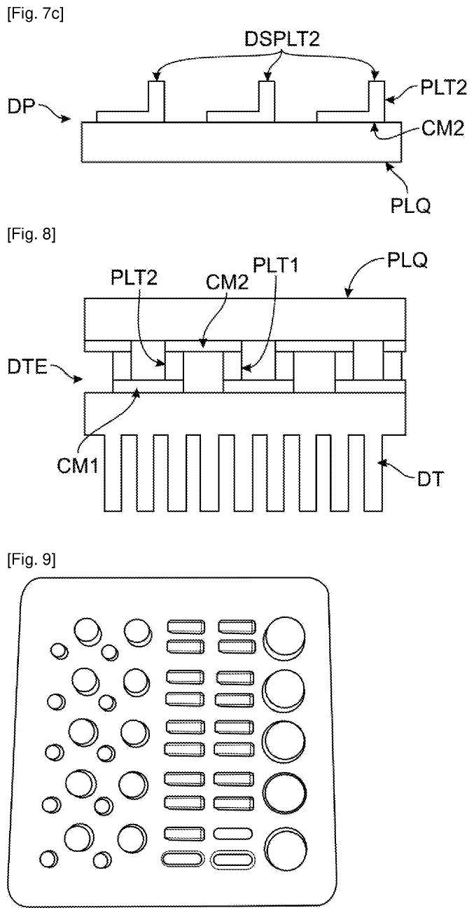

A plate PLQ made of an electrically insulating material is provided, which is shown in FIG. 7a.

A second series of metal connections DSCM2 is then deposited on the plate PLQ. This is done in the same pattern as the first series of metal connections PSCM1.

The result is the part shown in FIG. 7b.

A second series of studs DSPLT2 is then deposited, made of a semiconductor material with another type of doping (e.g. p-type) so that a semiconductor stud PLT2 is deposited on one and only one of the two ends of a metal connection CM2 of the second series of metal connections DSCM2.

Here too, the deposit is deposited using an additive manufacturing technique, such as one of those listed above. Advantageously, the same additive manufacturing technique as that used in step A) is chosen here.

This leads to the part shown in FIG. 7c, which forms the second portion DP of the thermoelectric device DTE.

Finally, step C) for assembling the second portion DP to the first portion PP of the thermoelectric device DTE is performed according to the following sub-steps.

Firstly, a free end of a semiconductor stud PLT1 of the first portion PP of the thermoelectric device DTE is arranged against a free end of each metal connection CM2 of the second portion DP of the thermoelectric device DTE. At the same time, a free end of a semiconductor stud PLT2 of the second portion DP of the thermoelectric device DTE is arranged against a free end of each metal connection CM1 of the first portion PP of the thermoelectric device DTE.

In practice, this means, for example, turning the second portion DP of the thermoelectric device DTE against the first portion PP of said device. Of course, as a variant, you may do the opposite—it's the same thing.

This is followed by a hot pressing step. This allows to ensure that the two portions PP, DP are held together.

The thermoelectric device DTE equipped with a heat sink DT that is finally obtained is shown in FIG. 8.

The heat sink DT supplied in step A) may be made, as a whole, from an electrically insulating material, which is also advantageously a good thermal conductor. This allows to avoid the risk of short circuits between the metal connections CM1, while ensuring an appropriate thermal behavior.

For example, a ceramic material may be chosen for this purpose. In this case, it is understood that it is not necessary to add a thermal paste or other material to assemble the heat sink to a thermoelectric module, as in the prior art. The thermal contact is therefore improved by reducing contact resistance at this point.

The plate PLQ supplied in step B) may then be made of a material identical to that of the heat sink DT supplied in step A).

Alternatively, the heat sink DT supplied in step A) comprises a heat dissipation structure SDT extending from its base BSE, said heat dissipation structure being made of a material selected from steel, for example 316L steel, Aluminum (Al), Titanium (Ti), a Copper Zirconium alloy (CuZr) or graphite. In this case, the base BSE of the heat sink DT is in the form of a surface layer made of a material chosen from a mica, a polymer or a ceramic, for example Marcor®. The aim is to ensure a good heat dissipation while avoiding the risk of short circuits between the various metal connections CM1.

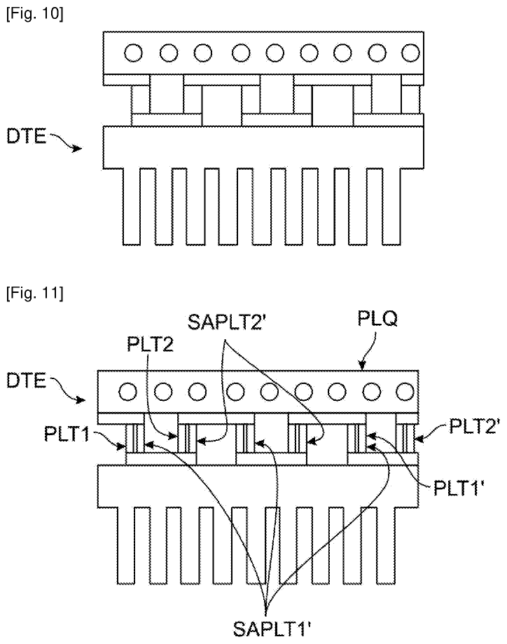

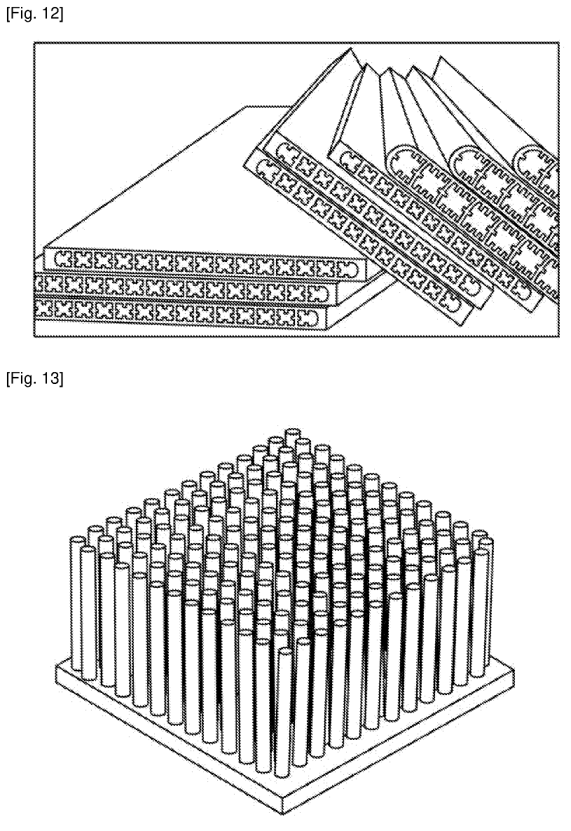

Note that the plate PLQ supplied in step B) may incorporate an enhanced heat dissipation function. In this way, the plate PLQ may be configured to form a further heat sink. This may be achieved, for example, by the presence of channels within the plate PLQ. This is shown, for example, in the variant shown in FIG. 10. FIG. 12 shows an example of a heat sink in the form of a plate equipped with channels. A fluid can then be circulated to increase heat transfer. The channels may also be structured to increase the exchange surface and/or the heat exchange coefficient.

The heat sink DT supplied in step A) can be designed in a variety of ways. In fact, the heat sink can incorporate a heat dissipation structure in the form of parallel-arranged fins, but also in the form of parallel-arranged studs, for example in the form of solid cylinders as shown in FIG. 13, or with channels as shown in FIG. 12.

FIG. 11 shows another thermoelectric device that may be obtained using the invention, wherein there are at least two semiconductor studs arranged in parallel at each metal connection end.

This allows to optimize the electrical output performance of the thermoelectric device DTE. In the prior art, all the semiconductor studs are electrically connected in series. In the prior art, all the semiconductor studs are electrically connected in series. This may lead to high output voltages (several volts), which are sometimes incompatible with the associated electronics. The possibility of connecting certain semiconductor studs in parallel allows to reduce this output voltage, while maintaining the power generated.

To obtain this, at least one series of additional studs SAPLT1′ made of a semiconductor material with the same type of doping as the semiconductor studs PLT1 of the first series of studs PSPLT1 is deposited during step A) so that an additional semiconductor stud PLT1′ is deposited at the end of each metal connection CM1 of the first series of metal connections PSCM1, parallel to the semiconductor stud PLT1 already present in the first series of studs PSPLT1. Similarly, during step B) at least one other series of additional studs SAPLT2′ made of a semiconductor material with the same type of doping as the studs PLT2 of the second series of studs PSPLT2 is deposited so that an additional semiconductor stud PLT2′ is deposited at the end of each metal connection CM2 of the second series of metal connections DSCM2, parallel to the semiconductor stud PLT2 already present in the second series of studs DSPLT2.

In the case in point, in FIG. 11, the plate PLQ is functionalized to incorporate a heat sink function, in this case by means of channels. Whichever variant is chosen, the material forming the semiconductor studs may be selected from Silicon (Si), Silicon Germanium (SiGe), Bismuth Telluride (Bi2Te3) or from the Skutterudite family. These materials may take the form of a powder that may be used for additive manufacturing.

Example of Embodiment: Thermoelectric Device Equipped with Heat Sink

The aim is to manufacture a thermoelectric device as shown in FIG. 8.

For step A), a heat sink DT made entirely of ceramic, of the finned type, is provided. The metal connections CM1 are made by physical vapor deposition (PVD) on the base BSE of the heat sink DT. Each cylindrical metal connection is made up as follows: Cu (thickness=200 nm)+Ni (thickness=5 μm)+Au (thickness=10 nm). The semiconductor studs PLT1 are obtained by powder bed melting, the powder being Silicon-Germanium (SiGe), in this case n-doped with a laser power of between 5 W and 200 W.

For step B), we start with a solid plate PLQ made from the same ceramic as the heat sink supplied in step A). The metal connections CM2 deposited on the plate PLQ are the same as those deposited on the base BSE of the heat sink DT (same dimensions, same materials, same deposition technique, same pattern, etc.). The semiconductor studs PLT2 are identical to the studs obtained in step A), the only difference being that they are p-doped, and they are obtained using the same method under the same conditions.

Finally, the hot pressing is performed for the assembly in step C). This hot pressing may be performed at a temperature of between 100° C. and 1000° C. over a period of between 1 minute and 10 hours.

### END OF THE EXAMPLE

The thermoelectric devices manufactured in this way may be used in all applications where a thermal gradient is available (e.g. transport, industry, etc.), the RTG (Radio-Isotope Thermoelectric Generators) applications for SiGe, the Peltier-type applications or to make thermal sensors.

1. A method for manufacturing a thermoelectric device (DTE) equipped with a heat sink (DT), comprising the following steps:
A) making (100) a first portion (PP) of said thermoelectric device (DTE), said first portion (PP) being equipped with a heat sink, according to the following sub-steps:
providing a heat sink (DT) equipped with a base (BSE), said base (BSE) being flat and made of an electrically insulating material,
depositing a first series of metal connections (PSCM1) on the base (BSE) of the heat sink (DT) in a predefined pattern, and
depositing, by additive manufacturing, a first series of studs (PSPLT1) made of a semiconductor material with a given type of doping so that a semiconductor stud (PLT1) is deposited on one and only one of the two ends of each metal connection (CM1) of the first series of metal connections (PSCM1),
B) producing (200) a second portion (DP) of the thermoelectric device (DTE) according to the following sub-steps:
supplying a plate (PLQ) made of an electrically insulating material,
depositing a second series of metal connections (DSCM2) on said plate (PLQ), in a pattern identical to that of the first series of metal connections (PSCM1), and
depositing, by additive manufacturing, a second series of studs (DSPLT2) made of a semiconductor material with another type of doping so that a semiconductor stud (PLT2) is deposited on one and only one of the two ends of a metal connection (CM2) of the second series of metal connections (DSCM2),
C) assembling (300) the second portion (DP) of the device to the first portion (PP) of the device according to the following sub-steps:
arranging a free end of a semiconductor stud (PLT1) of the first portion (PP) of the device against a free end of each metal connection (CM1) of the second portion (DP) of the device, and at the same time, arranging a free end of a semiconductor stud (PLT2) of the second portion (DP) of the device against a free end of each metal connection (CM1) of the first portion (PP) of the device, and
performing a hot pressing.

2. The method according to claim 1, wherein the heat sink (DT) supplied in step A) is made, as a whole, of an electrically insulating material, for example ceramic.

3. The method according to claim 2, wherein the plate (PLQ) supplied in step B) is made of a material identical to that of the heat sink (DT) supplied in step A).

4. The method according to claim 1, wherein the heat sink (DT) provided in step A) comprises a heat dissipating structure (SDT) extending from its base, said heat dissipating structure being made of a material selected from steel, for example 316L steel, Aluminum (Al), Titanium (Ti), Copper Zirconium alloy (CuZr) or graphite.

5. The method according to claim 4, wherein the base (BSE) of the heat sink (DT) is made of a material chosen from a mica, a polymer or a ceramic, for example Marcor®.

6. The method according to claim 1, wherein the plate (PLQ) provided in step B) is configured to form a further heat sink, for example by the presence of channels within said plate.

7. The method according to claim 1, wherein the heat sink supplied in step A) is chosen from a finned heat sink, a stud heat sink, for example formed from solid cylinders, or a channel heat sink.

8. The method according to claim 1, wherein:
during step A), at least one series of additional studs (SAPLT1′) made of a semiconductor material with the same type of doping as the semiconductor studs (PLT1) of the first series of studs (PSPLT1) is deposited so that an additional semiconductor stud (PLT1′) is deposited at the end of each metal connection (CM1) of the first series of metal connections (PSCM1), parallel to the semiconductor stud (PLT1) already present in the first series of studs (PSPLT1);
during step B), at least one other series of additional studs (SAPLT2′) made of a semiconductor material with the same type of doping as the studs (PLT2) of the second series of studs (PSPLT2) is deposited so that an additional semiconductor stud (PLT2′) is deposited at the end of each metal connection (CM2) of the second series of metal connections (DSCM2), parallel to the semiconductor stud (PLT2) already present in the second series of studs (DSPLT2).

9. The method according to claim 1, wherein the material forming the semiconductor studs (PLT1, PLT1′, PLT2, PLT2′) is chosen from Silicon (Si), Silicon Germanium (SiGe), Bismuth Telluride (Bi2Te3), or from the Skutterudite family.

10. The method according to claim 1, wherein said additive manufacturing technique is selected from:
the laser melting on a powder bed, for example the selective laser melting (SLM) or selective laser sintering (SLS), or
the direct energy deposit (DED).
